(19) United States
(12) Patent Application Publication
(10) Pub. No.: US 2019/0371891 A1
(43) Pub. Date: Dec. 5, 2019

(54) BULK LAYER TRANSFER BASED SWITCH WITH BACKSIDE SILICIDATION

(71) Applicant: QUALCOMM Incorporated, San Diego, CA (US)

(72) Inventors: Sinan GOKTEPELI, San Diego, CA (US); George Pete IMTHURN, San Diego, CA (US); Ravi Pramod Kumar VEDULA, San Diego, CA (US); Peter CLARKE, San Diego, CA (US)

(21) Appl. No.: 15/996,320

(22) Filed: Jun. 1, 2018

(51) Int. Cl. H01L 29/10; H01L 29/06; H01L 29/861; H01L 29/78; H01L 29/45; H01L 29/66; H01L 21/762; H01L 49/02; H01L 21/3205; H01L 23/66; H01L 21/8234; H01L 27/06; H01L 21/306

(52) U.S. Cl. CPC H01L 29/1095; H01L 23/528; H01L 29/1087; H01L 29/861; H01L 29/7851; H01L 29/45; H01L 29/66795; H01L 21/76224; H01L 29/66136; H01L 28/20; H01L 21/32053; H01L 23/66; H01L 21/823431; H01L 27/0629; H01L 21/30625; H01L 2223/6677; H01L 29/0649

(57) ABSTRACT

A radio frequency integrated circuit switch includes a semiconductor die with a transistor having a gate on a first-side (e.g., front-side) of the semiconductor die. The semiconductor die may include a bulk semiconductor substrate or wafer (e.g., silicon substrate or wafer). The semiconductor die may also include a first deep trench isolation (DTI) region that extends from the front-side to a backside opposite the front-side of the semiconductor die. The radio frequency integrated circuit switch further includes a body contact layer on the backside of the semiconductor die. The body contact layer is coupled to a backside of a body of the transistor. The body of the transistor may have a first P-type region (e.g., a P+ region).

### TECHNICAL FIELD

The present disclosure generally relates to integrated circuits (ICs). More specifically, the present disclosure relates to a switch implemented on a bulk layer transfer wafer with backside silicidation.

### BACKGROUND

Designing mobile radio frequency (RF) chips (e.g., mobile RF transceivers) is complicated by added circuit functions for supporting communication enhancements. Designing these mobile RF transceivers may include using semiconductor on insulator technology. Semiconductor on insulator (SOI) technology replaces conventional semiconductor (e.g., silicon) substrates with a layered semiconductor-insulator-semiconductor substrate for reducing parasitic capacitance and improving performance. SOI-based devices differ from conventional, silicon-built devices because a silicon junction is above an electrical isolator, typically a buried oxide (BOX) layer. A reduced thickness BOX layer, however, may not sufficiently reduce artificial harmonics caused by the proximity of an active device on the SOI layer and an SOI substrate supporting the BOX layer.

For example, high performance complementary metal oxide semiconductor (CMOS) radio frequency (RF) switch technologies are currently manufactured using SOI substrates. While SOI substrates may provide some protection against artificial harmonics in mobile RF transceivers, SOI substrates are very expensive. Furthermore, increasing device isolation and reducing RF loss may involve expensive handle wafers. For example, a CMOS switch device may be physically bonded to a high resistivity (HR) handle wafer, such as HR-silicon or sapphire. While the increased spatial separation of the switch device from the underlying substrate dramatically improves the RF performance of the CMOS switch, using HR-silicon or sapphire handle wafer dramatically drives up cost. That is, using SOI wafers and handle substrates is quite expensive relative to the cost of a bulk semiconductor wafer.

### SUMMARY

A radio frequency integrated circuit switch includes a semiconductor die including a transistor having a gate on a front-side of the semiconductor die, and a first deep trench isolation region that extends from the front-side to a backside opposite the front-side of the semiconductor die. The radio frequency integrated circuit switch also includes a body contact layer on the backside of the semiconductor die. The body contact layer is coupled to a backside of a body of the transistor. The body includes a first P-type region.

A method of constructing a radio frequency integrated circuit switch may include fabricating a transistor having a gate on a front-side of a semiconductor die. The method also includes forming a first deep trench isolation region extending from the front-side to a backside opposite the front-side of the semiconductor die. The method further includes depositing a body contact layer on the backside of the semiconductor die. The body contact layer is coupled to a backside of a body of the transistor. The body includes a first P-type region.

A radio frequency front end module includes a wireless transceiver. The wireless transceiver includes a semiconductor die with a transistor having a gate on a front-side of the semiconductor die, a first deep trench isolation region extending from the front-side to a backside opposite the front-side of the semiconductor die, and a body contact layer on the backside of the semiconductor die. The body contact layer is coupled to a backside of a body of the transistor. The body includes a first P-type region. The radio frequency front end module further includes an antenna coupled to an output of the wireless transceiver.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a radio frequency (RF) front end module.

FIGS. 2A to 2D show cross-sectional views of a radio frequency integrated circuit (RFIC) during a layer transfer process.

FIG. 3 is a cross-sectional view of a radio frequency integrated circuit (RFIC) fabricated using a bulk semiconductor layer transfer process according to aspects of the present disclosure.

FIG. 4 is a cross-sectional view of a radio frequency integrated circuit having a bulk semiconductor wafer including a contact layer on a backside of the bulk semiconductor wafer, according to aspects of the present disclosure.

FIGS. 5A-5G illustrate a process for fabricating the radio frequency integrated circuit, according to aspects of the present disclosure.

FIG. 6 illustrates an exemplary layout of a switch having an H-gate structure.

FIG. 7 is a cross-sectional view of a radio frequency integrated circuit switch having a bulk semiconductor wafer including a body tie on a backside of the bulk semiconductor wafer, according to aspects of the present disclosure.

FIG. 8 is a cross-sectional view of a radio frequency integrated circuit switch having a bulk semiconductor wafer including a body tie on a backside of the bulk semiconductor wafer, according to aspects of the present disclosure.

FIG. 9 illustrates an exemplary schematic of a radio frequency integrated circuit switch.

FIG. 10 is a cross-sectional view of a radio frequency integrated circuit switch having a bulk semiconductor wafer including a body tie on a backside of the bulk semiconductor wafer, according to aspects of the present disclosure.

FIG. 11 is a cross-sectional view of a radio frequency integrated circuit switch having a bulk semiconductor wafer including a body tie on a backside of the bulk semiconductor wafer, according to aspects of the present disclosure.

FIG. 12 illustrates an exemplary schematic of a radio frequency integrated circuit switch.

FIG. 13 illustrates an exemplary layout of a switch according to aspects of the present disclosure.

FIG. 14 is a process flow diagram illustrating a method of constructing a radio frequency integrated circuit switch using a bulk semiconductor layer transfer process according to aspects of the present disclosure.

FIG. 15 is a block diagram showing an exemplary wireless communication system in which a configuration of the present disclosure may be advantageously employed.

FIG. 16 is a block diagram illustrating a design workstation used for circuit, layout, and logic design of a semiconductor component according to one configuration of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Designing mobile radio frequency (RF) transceivers may include using semiconductor on insulator technology. Semiconductor on insulator (SOI) technology replaces conventional silicon substrates with a layered semiconductor-insulator-semiconductor substrate for reducing parasitic capacitance and improving performance. While SOI-based devices differ from conventional, silicon-built devices by including a silicon junction above an electrical isolator, typically a buried oxide (BOX) layer, SOI-based devices are more expensive than conventional, silicon-built devices. Furthermore, a reduced thickness BOX layer may not sufficiently reduce artificial harmonics caused by the proximity of an active device on an SOI layer and an SOI substrate supporting the BOX layer.

The active devices on the SOI layer may include high performance complementary metal oxide semiconductor (CMOS) transistors. For example, high performance CMOS RF switch technologies are currently manufactured using SOI substrates. A radio frequency front end (RFFE) module may rely on these high performances CMOS RF switch technologies for successful operation. A process for fabricating an RFFE module, therefore, involves the costly integration of an SOI wafer for supporting these high performances CMOS RF switch technologies. Furthermore, supporting future RF performance enhancements involves increasing device isolation while reducing RF loss.

Transistors fabricated using SOI technology may suffer from the floating body effect. The floating body effect is a phenomenon in which the transistor's body collects charge generated at the junction of the transistor device. Unfortunately, charge that accumulates in the body causes adverse effects, such as parasitic transistors in the structure and off-state leakage. In addition, the accumulated charge also causes dependence of the threshold voltage of the transistor on its previous states. This effect (e.g., a floating body effect) may also generate artificial harmonic frequencies, which are detrimental to communication enhancements such as carrier aggregation.

While SOI wafers may reduce some artificial harmonics, SOI wafers are expensive. Moreover, switch device fabrication using complementary metal oxide semiconductor technology may be complicated by the floating body effect. The floating body effect may be mitigated by tying the body to, for example, the gate in an RF switch device. Unfortunately, the body ties and the gate contacts have to route out and around source/drain metallization, creating area loss in the radio frequency switch device. Furthermore, extraction of charge within the body of radio frequency switch devices is challenging, often resulting in reducing a width of the radio frequency switch devices. Consequently, achieving sufficient switch performance may involve using several narrow switches.

Various aspects of the present disclosure provide techniques for bulk layer transfer processing with backside silicidation. The process flow for semiconductor fabrication of the integrated radio frequency circuit may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to a substrate of a wafer that is not diced. Similarly, the terms chip and die may be used interchangeably.

Aspects of the present disclosure include using a bulk semiconductor (e.g., silicon) wafer instead of SOI wafers to fabricate a radio frequency integrated circuit switch. Inexpensive bulk semiconductor wafers may be used to form a semiconductor device layer without using an expensive SOI wafer.

In one aspect of the present disclosure, the radio frequency integrated circuit switch includes a semiconductor die that includes a transistor having a gate on a first-side (e.g., front-side) of the semiconductor die. The semiconductor die may include a bulk semiconductor substrate or wafer (e.g., silicon substrate or wafer). The transistor may have a Fin field effect transistors (FinFET) structure or a tri-gate structure. A first deep trench isolation (DTI) region extends from the front-side to a second-side (e.g., backside) opposite the front-side of the semiconductor die. The radio frequency integrated circuit switch further includes a body contact layer on the backside of the semiconductor die. The body contact layer is coupled to a backside of a body of the transistor. The body of the transistor may include a first P-type region (e.g., a P+ region). In the P+ region, holes are the majority charge carriers whereas in N-type (e.g., N+) regions, free electrons are the majority charge carriers. Furthermore, the body contact layer may be used as a backside body tie. The backside body tie enables flexibility in a width of the radio frequency integrated circuit switch, which can be as narrow or as wide as desirable because there is less limitation on the width of this radio frequency integrated circuit switch relative to an SOI wafer switch.

In some aspects, the body contact layer may be a silicide layer deposited on the backside of the bulk semiconductor substrate or wafer. For example, the body contact layer is on an entire length of the backside of the bulk semiconductor substrate. In one aspect, the P+ region, which is a body of the transistor, may be part of or coupled to the bulk semiconductor substrate. For example, portions of the bulk semiconductor region may be doped to form the P+ region. The radio frequency integrated circuit switch may also include a backside dielectric layer on the body contact layer, in which the first deep trench isolation region extends through the body contact layer and into the backside dielectric layer. In some aspects of the present disclosure, the body of the transistor further includes an N+ region between the P+ region and the body contact layer to form an embedded diode.

The body of the transistor may further include a P− region between the body of the first transistor and the P+ region to form an internal body resistor. For example, the body of the radio frequency integrated circuit switch may include a first section, which is the first P-type region or P+ region, and a second section as a second P-type region or the P− region. The second P-type region is less doped or has less doping concentration than the first P-type region. The diode formed may be a P-N junction diode (e.g., a Schottky diode). The P-N junction is created by doping, for example by ion implantation, diffusion of dopants, or by epitaxy (growing a layer of crystal doped with one type of dopant on top of a layer of crystal doped with another type of dopant).

In addition, the backside of the bulk semiconductor wafer may be supported by a backside dielectric layer (e.g., a second-side dielectric layer) distal from a front-side dielectric layer (e.g., a first-side dielectric layer) on the semiconductor device layer. The RFIC may also include a handle substrate on the front-side dielectric layer. The front-side and backside may each be referred to as a first-side or a second-side. In some cases, the front-side will be referred to as the first-side. In other cases, the backside will be referred to as the first-side.

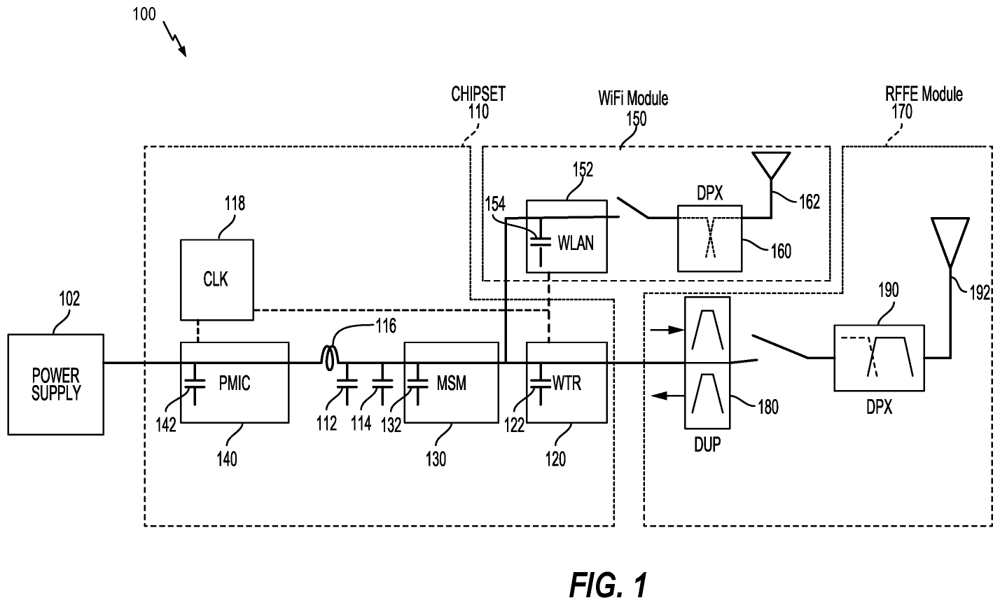

FIG. 1 is a schematic diagram of a wireless device 100 (e.g., a cellular phone or a smartphone) having a switch implemented on a bulk layer transfer wafer with backside silicidation, according to aspects of the present disclosure. The wireless device 100 may include a wireless local area network (WLAN) (e.g., WiFi) module 150 and an RF front end module 170 for a chipset 110. The WiFi module 150 includes a first diplexer 160 communicably coupling an antenna 162 to a wireless local area network module (e.g., WLAN module 152). The RF front end module 170 includes a second diplexer 190 communicably coupling an antenna 192 to the wireless transceiver 120 (WTR) through a duplexer 180 (DUP).

The wireless transceiver 120 and the WLAN module 152 of the WiFi module 150 are coupled to a modem (MSM, e.g., a baseband modem) 130 that is powered by a power supply 102 through a power management integrated circuit (PMIC) 140. The chipset 110 also includes capacitors 112 and 114, as well as an inductor(s) 116 to provide signal integrity. The PMIC 140, the modem 130, the wireless transceiver 120, and the WLAN module 152 each include capacitors (e.g., 142, 132, 122, and 154) and operate according to a clock 118. The geometry and arrangement of the various inductor and capacitor components in the chipset 110 may reduce the electromagnetic coupling between the components.

The wireless transceiver 120 of the wireless device generally includes a mobile radio frequency (RF) transceiver to transmit and receive data for two-way communication. A mobile RF transceiver may include a transmit section for data transmission and a receive section for data reception. For data transmission, the transmit section may modulate an RF carrier signal with data to obtain a modulated RF signal, amplify the modulated RF signal using a power amplifier (PA) to obtain an amplified RF signal having the proper output power level, and transmit the amplified RF signal via the antenna 192 to a base station. For data reception, the receive section may obtain a received RF signal via the antenna 192 and may amplify the received RF signal using a low noise amplifier (LNA) and process the received RF signal to recover data sent by the base station in a communication signal.

The wireless transceiver 120 may include one or more circuits for amplifying these communication signals. The amplifier circuits (e.g., LNA/PA) may include one or more amplifier stages that may have one or more driver stages and one or more amplifier output stages. Each of the amplifier stages includes one or more transistors configured in various ways to amplify the communication signals. Various options exist for fabricating the transistors that are configured to amplify the communication signals transmitted and received by the wireless transceiver 120.

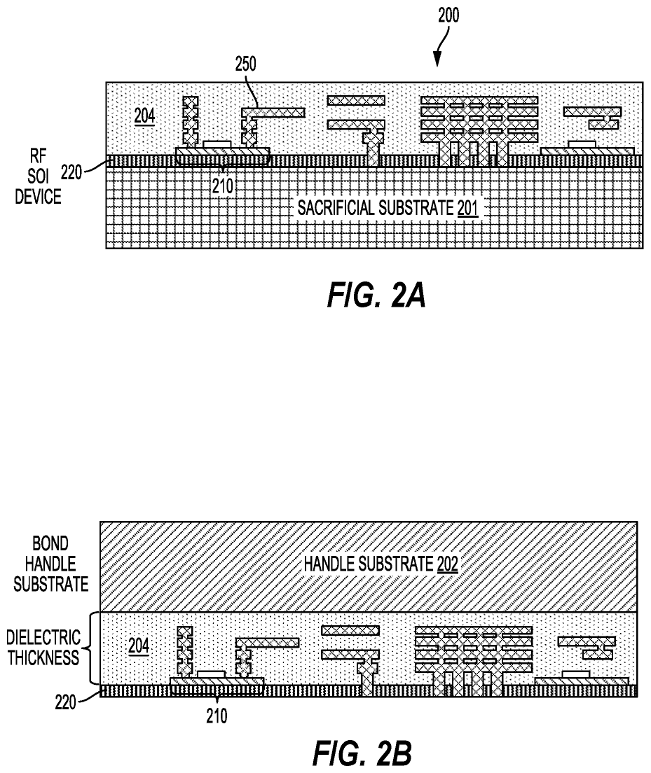

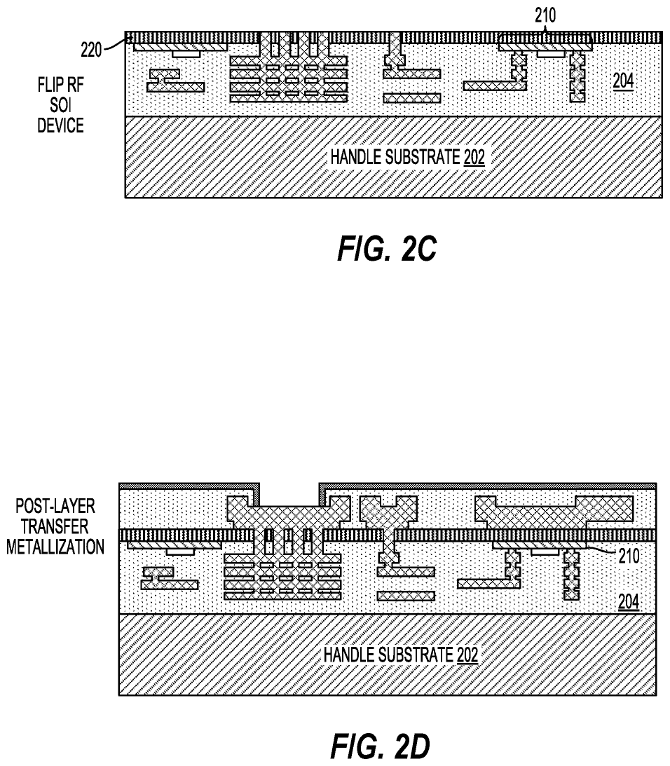

The wireless transceiver 120 and the RF front end module 170 may be implemented using a layer transfer process to further separate the active device from a substrate as shown in FIGS. 2A to 2D.

FIGS. 2A to 2D show cross-sectional views of a radio frequency (RF) integrated circuit 200 during a layer transfer process according to aspects of the present disclosure. As shown in FIG. 2A, an RF device includes an active device 210 on an insulator layer 220 supported by a sacrificial substrate 201 (e.g., a bulk wafer). The RF device also includes interconnects 250 coupled to the active device 210 within a first dielectric layer 204. As shown in FIG. 2B, a handle substrate 202 is bonded to the first dielectric layer 204 of the RF device. In addition, the sacrificial substrate 201 is removed. Removal of the sacrificial substrate 201 using the layer transfer process enables high-performance, low-parasitic RF devices by increasing the dielectric thickness. That is, a parasitic capacitance of the RF device is proportional to the dielectric thickness, which determines the distance between the active device 210 and the handle substrate 202.

As shown in FIG. 2C, the RF device is flipped once the handle substrate 202 is secured and the sacrificial substrate 201 is removed. As shown in FIG. 2D, a post layer transfer metallization process is performed using, for example, a regular complementary metal oxide semiconductor (CMOS) process.

The active device 210 on the BOX layer 220 may be a complementary metal oxide semiconductor (CMOS) transistor. The RFFE module 170 (FIG. 1) may rely on these high performance CMOS RF switch technologies for successful operation.

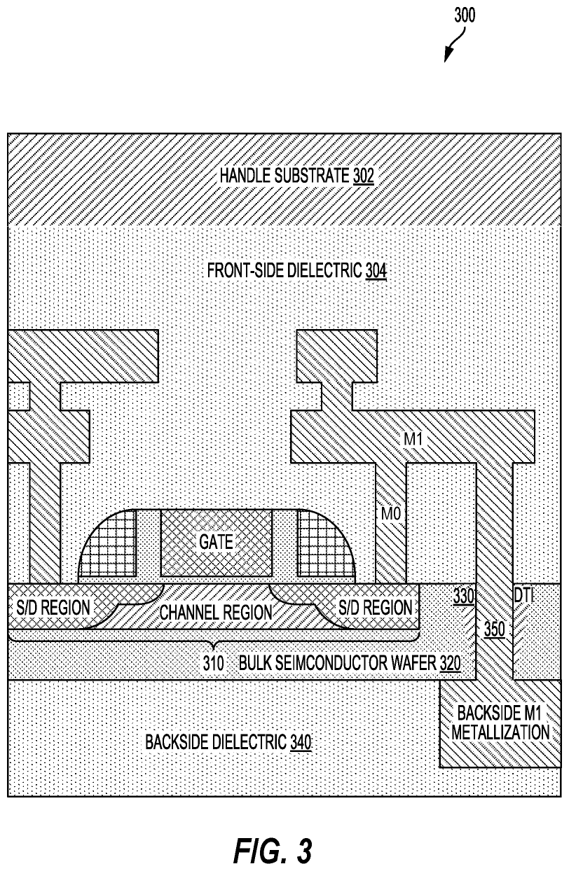

FIG. 3 is a cross-sectional view of a radio frequency integrated circuit (RFIC) fabricated using a bulk semiconductor layer transfer process according to aspects of the present disclosure. Representatively, an RF integrated circuit 300 includes an active device 310 having a gate, source/drain (S/D) regions, and a channel region between the source/drain regions, each formed on a front-side of a bulk semiconductor wafer 320. In contrast to SOI implementations, an active device layer including the source/drain and channel regions is not supported by a buried oxide (BOX) layer. Although shown as an active device, it should be recognized that the active device 310 may be a first active/passive device, as well as a second active/passive device.

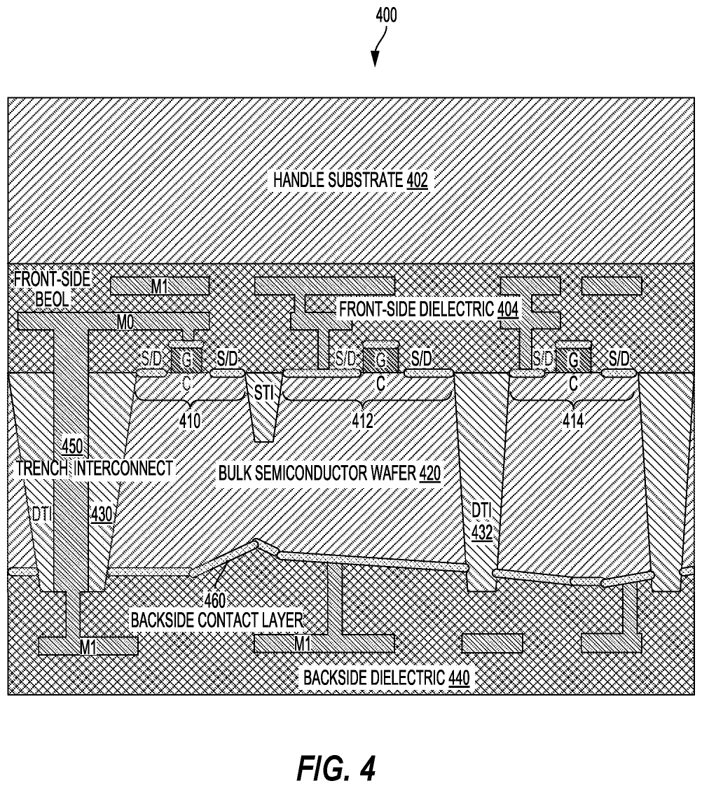

The RF integrated circuit 300 also includes middle-of-line (MOL)/back-end-of-line (BEOL) interconnects coupled to the source/drain regions of the active device 310. As described, the MOL/BEOL layers may be referred to as first-side (e.g., front-side) layers. By contrast, the layers supporting the bulk semiconductor wafer 320 may be referred to as second-side (e.g., backside) layers. In this example, a front-side metallization layer M1 is coupled to the source/drain regions of the active device 310 and arranged in a front-side dielectric layer 304. In addition, a handle substrate 302 is coupled to the front-side dielectric layer 304. A backside dielectric 340 is adjacent to and possibly supports the bulk semiconductor wafer 320. In addition, a backside M1 metallization layer (e.g., a second-side metallization layer) is coupled to the front-side metallization layer M1 with a trench interconnect 350 through a deep trench isolation (DTI) region 330 extending from the front-side to the backside of the bulk semiconductor wafer 320, as further illustrated in FIG. 4.

FIG. 4 is a cross-sectional view of a radio frequency integrated circuit (RFIC) having a bulk semiconductor wafer including a contact layer on a backside of the bulk semiconductor wafer, according to aspects of the present disclosure. Representatively, an RF integrated circuit 400 includes a first active device 410, a second active device 412, and a third active device 414, each having a gate (G), source/drain (S/D) regions, and a channel (C) region between the source/drain regions, each formed on a front-side of a bulk semiconductor wafer 420 (e.g., a bulk silicon wafer). In contrast to SOI implementations, an active device layer including the source/drain and channel regions of the active devices (e.g., 410, 412, and 414) is not supported by a buried oxide (BOX) layer.

Although shown as a first active device, it should be recognized that the first active device 410 may be a first active/passive device, as well as a second active/passive device, such as the second active device 412. In addition, although shown as planar devices, it should be recognized that the active devices (e.g., 410, 412, and 414) are not limited to planar devices. For example, the active devices (e.g., 410, 412, and 414) may include, but are not limited to, planar field effect transistors (FETs), fin-type FETs (FinFETs), nanowire FETs, or other like FETs.

The RF integrated circuit 400 also includes MOL interconnects (M0) as well as BEOL interconnects (M1) coupled to the gate as well as the source/drain regions of the active devices (e.g., 410, 412, and 414). The MOL interconnects may include trench interconnects (e.g., CA, CB) and vias (e.g., V0) for coupling active devices formed during a front-end-of-line to metallization layers formed during the back-end-of-line processing. In this example, an MOL interconnect M0 is coupled to a gate contact (e.g., a poly contact) of the gate of the first active device 410 and arranged in a front-side dielectric layer 404. In addition, a handle wafer 402 (handle substrate) is coupled to the front-side dielectric layer 404. A backside dielectric layer 440 is adjacent to and possibly supports the bulk semiconductor wafer 420.

In this configuration, a backside M1 metallization layer (e.g., a second-side metallization layer) is coupled to the front-side MOL zero interconnect M0 through a trench interconnect 450. The trench interconnect 450 extends through a first deep trench isolation (DTI) region 430, from the front-side to the backside of the bulk semiconductor wafer 420. The backside metallization M1 may also be coupled to a backside contact layer 460.

According to aspects of the present disclosure, the first DTI region 430 extends though the backside contact layer 460 and into the backside dielectric layer 440. Similarly, a second deep trench isolation (DTI) region 432 extends though the backside contact layer 460 and into the backside dielectric layer 440. In this example, the backside contact layer 460 is deposited along the backside of the bulk semiconductor wafer 420. The backside contact layer 460 may be composed of a silicide material or other like conductive material. The backside contact layer 460 also contacts a portion of the first DTI region 430 that extends from the backside of the bulk semiconductor wafer 420. In addition, the backside dielectric layer 440 contacts the remaining portion of the first DTI region 430 that extends from the backside of the bulk semiconductor wafer 420.

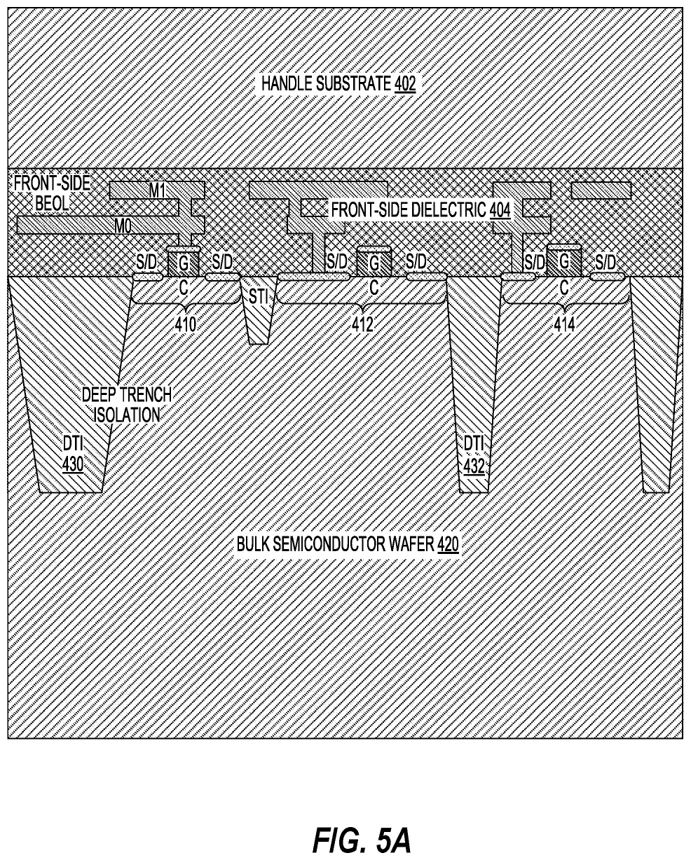

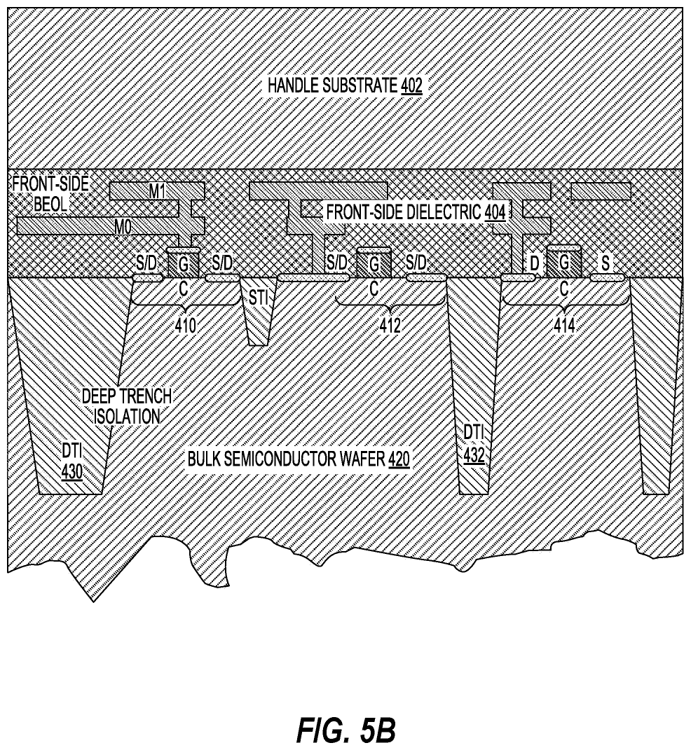

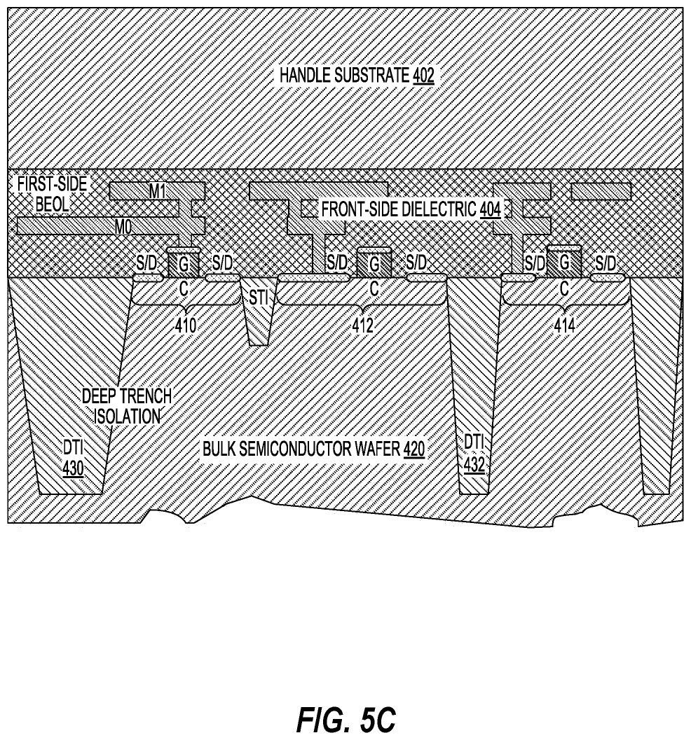

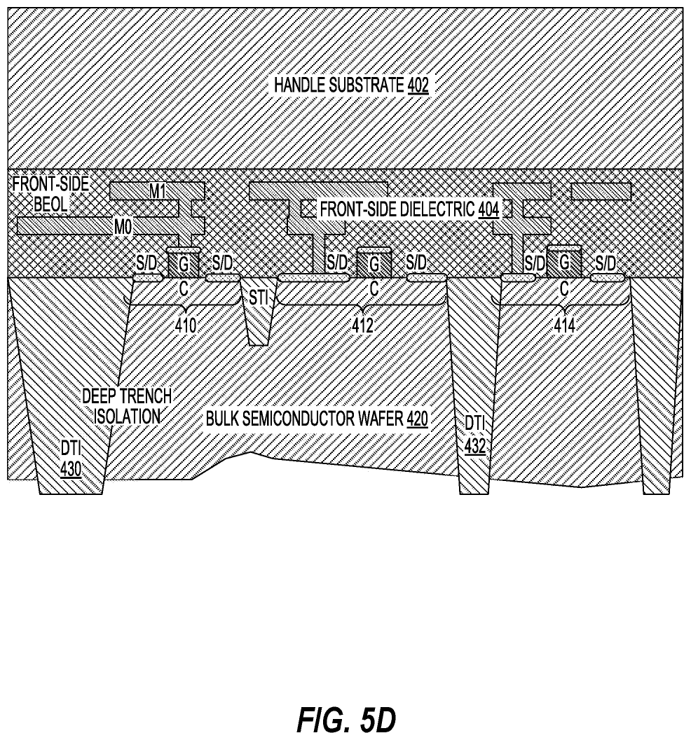

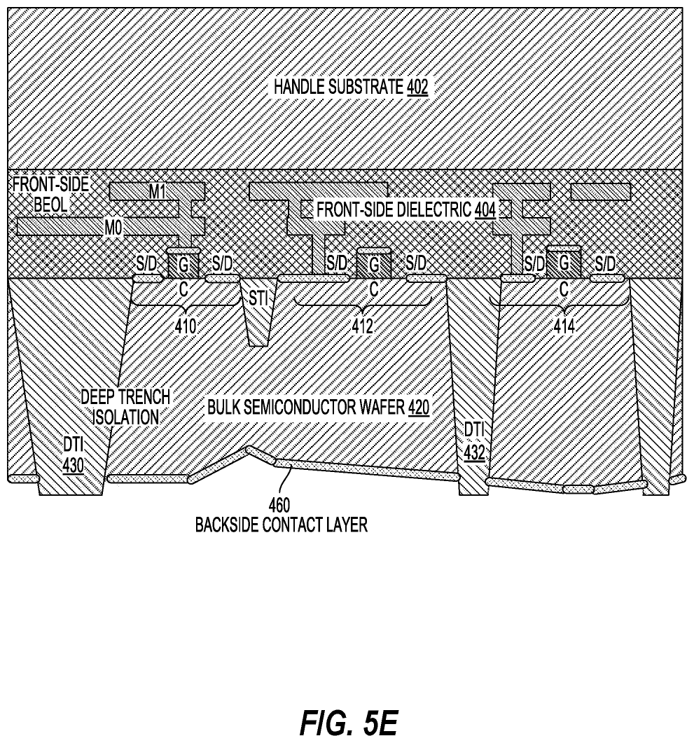

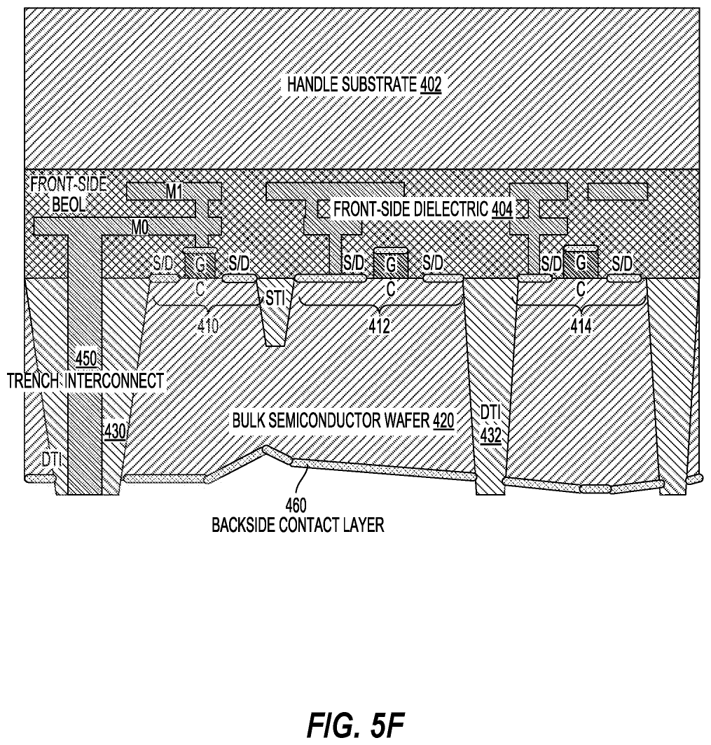

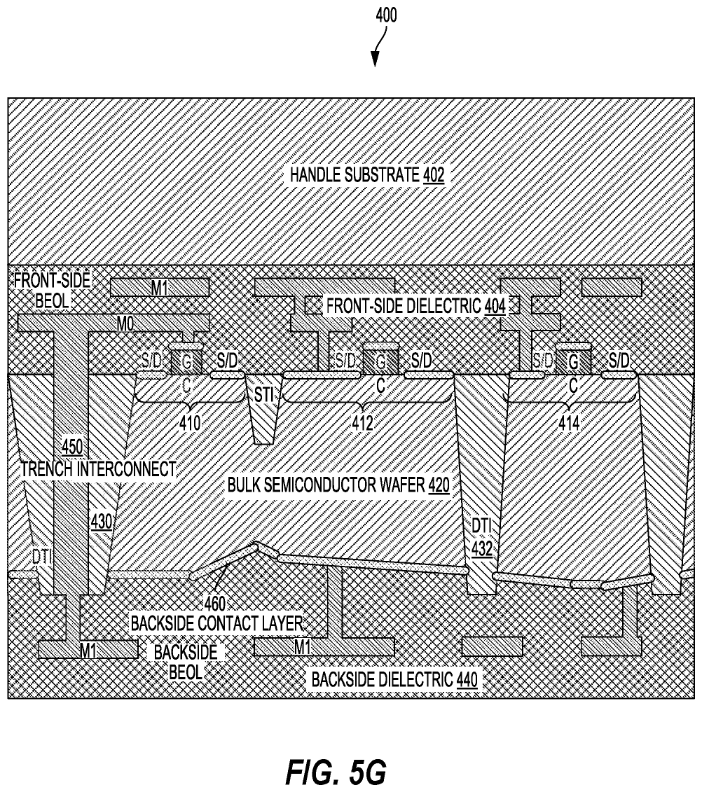

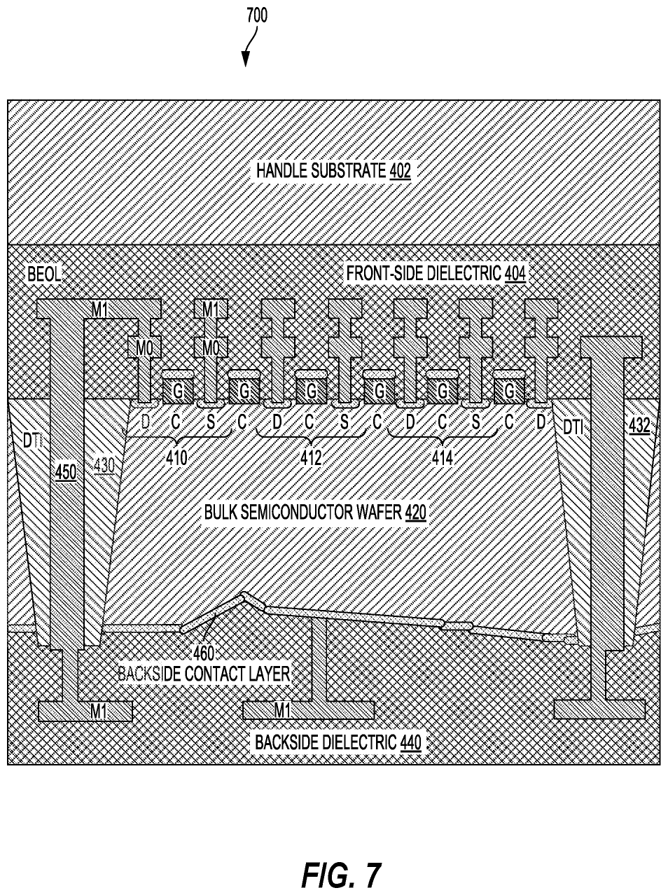

The layer transfer process shown in FIGS. 2A-2D may be used with bulk semiconductor wafers to create CMOS products (e.g., a CMOS transistor) without using expensive SOI substrates, as shown in FIG. 4. Various aspects of the present disclosure provide techniques for bulk layer transfer processing with backside silicidation, as described in FIGS. 5A-5G. One aspect of the present disclosure uses a bulk layer transfer process with backside silicidation to form an RF integrated circuit, for example, as shown in FIGS. 7, 8, 10, and 11.

FIGS. 5A-5G illustrate a process for fabricating the RF integrated circuit 400 of FIG. 4, according to aspects of the present disclosure. FIG. 5A illustrates an initial step for forming the RF integrated circuit 400 of FIG. 4. This process may begin with a complementary metal oxide semiconductor (CMOS) wafer, such as a bulk silicon wafer. Next, CMOS front-end-of-line integration is performed on the bulk semiconductor wafer 420 to form the first active device 410, the second active device 412, and the third active device 414. In this example, the first active device 410 and the second active device 412 are separated by a shallow trench isolation (STI) region. By contrast, the second active device 412 and the third active device 414 are separated by the second DTI region 432.

According to aspects of the present disclosure, STI regions are used for active device separation, whereas the DTI regions are used for post layer transfer separation. A depth of the first DTI region 430 and the second DTI region 432 may be in the range of 0.4 to 4 micrometers, although the depth of the first DTI region 430 and the second DTI region 432 may be reduced for future processes. The DTI regions as well as the STI regions may be filed with a similar dielectric material, such as silicon dioxide (SiO₂) and formed prior to the active devices.

Once the active devices are formed, MOL processes connect the active devices to BEOL interconnect layers. In this example, a zero-layer interconnect M0 is coupled to the gate G of the first active device 410. In addition, a first BEOL interconnect M1 is coupled to the zero-layer interconnect M0. The first BEOL interconnect M1 is formed as part of a front-side BEOL process. This process is followed by depositing the front-side dielectric layer 404. Once the front-side dielectric layer 404 is deposited, the handle wafer 402 is bonded to the front-side dielectric layer 404. The handle wafer 402 can be a processed wafer or a bare wafer.

FIG. 5B illustrates a backgrind process of the bulk semiconductor wafer 420. This initial backgrind process is applied to the backside of the bulk semiconductor wafer 420, distal from the active device layer. This initial backgrind process may leave a variation of about 5 to 10 micrometers. The backgrind process continues in FIG. 5C, in which a chemical mechanical polish (CMP) process is applied to the backside of the bulk semiconductor wafer 420. This CMP process may reduce the surface variation of the backside of the bulk semiconductor wafer 420 to a range of 0.1 micrometers to 0.4 micrometers, but preferably to 0.1 micrometers. This CMP process does not expose the first DTI region 430 or the second DTI region 432.

As shown in FIG. 5B, the backgrind process may be applied to the backside of the bulk semiconductor wafer 420 with a surface variation of 5-10 microns. The surface variation may be reduced by polishing the backside of the bulk semiconductor wafer 420 to a predetermined surface variation (e.g., less than 0.3 microns), as shown in FIG. 5C. In addition, a silicon etch (e.g., potassium hydroxide (KOH) or tetramethylammonium hydroxide (TMAH)), a CMP (chemical mechanical polish), or combination of CMP and etching may be performed to reduce a thickness of the bulk semiconductor wafer to a thickness equal to or less than a thickness of the DTI regions.

As shown in FIG. 5D, the silicon etch/CMP is performed on the backside of the bulk semiconductor wafer 420 for exposing a portion of the first DTI region 430 as well as the second DTI region 432. In a further aspect of the present disclosure, an etch stop layer may be formed in the bulk semiconductor wafer 420 for improving a planarity of the backside of the bulk semiconductor wafer 420. Once the first DTI region 430 and the second DTI region 432 are exposed, a post-layer transfer silicide layer may be deposited on an entire length of the backside of the bulk semiconductor wafer 420 for forming the backside contact layer 460, as shown in FIG. 5E.

As shown in FIG. 5F a trench interconnect 450 is formed through the first DTI region 430. In this example, the trench interconnect 450 is coupled to the front-side zero interconnect M0 in the front-side dielectric layer 404. As shown in FIG. 5G, the RF integrated circuit 400 is completed by forming the backside BEOL interconnects M1 and depositing the backside dielectric layer 440. The backside dielectric layer 440 is deposited on the backside of the bulk semiconductor wafer 420 and exposed sidewalls of the first DTI region 430 that extend from the backside of the bulk semiconductor wafer 420. In this example, the backside dielectric layer 440 is distal from the front-side dielectric layer 404. In this example, the backside BEOL interconnect M1 is coupled to the front-side zero interconnect M0 through the trench interconnect 450.

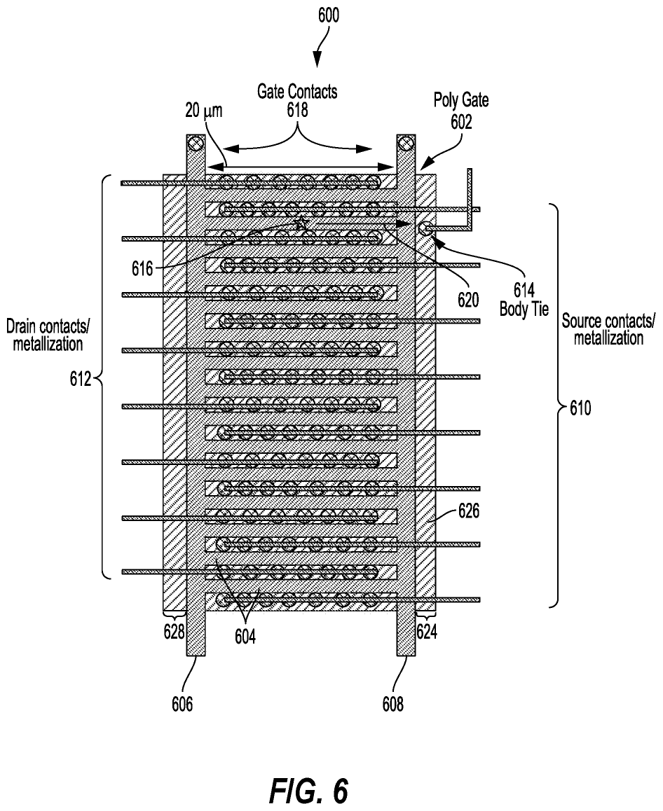

FIG. 6 illustrates an exemplary layout of a switch 600 having an H-gate structure 602. The H-gate structure 602 may include a polysilicon gate. Although an H-gate structure is described, other gate structures such as a T-gate structure are equally applicable. The H-gate structure 602 may include multiple cross elements 604 connected between a first parallel element 606 and a second parallel element 608. An active region of the switch 600 includes a source region and a drain region. The source region includes source contacts or metallization 610 and the drain region includes drain contacts or metallization 612. The source contacts 610 and drain contacts 612 may be coupled to a channel region adjacent to or underlying the multiple cross elements 604 of the polysilicon gate. An electrical potential may be established at the source regions and the drain regions.

The active region of the switch 600 can be implanted with a heavy implant of ions to the source and drain regions. As a result, a portion of active region that lies below the gate serves as a body 626 of the switch 600 and the portions that are not below the gate serve as the source and drain. In some implementations, the body 626 extends below the source and drain regions. For example, if the switch 600 is implemented on a bulk substrate, the body 626 includes a region of the substrate below the source and drain that was not altered by the heavy implant.

The switch 600 may also include a conductive body tie or metallization 614 and gate contacts 618. The contacts substantially complicate routing within the switch 600. For example, the body tie 614 and the gate contacts 618 are routed out and around the source and the drain metallization, which creates area losses. Additional width (e.g., 624 and/or 628) of the body 626 of the switch 600 may be created to accommodate the body tie 614. The switch 600 in this case is implemented in accordance with a structure (e.g., SOI wafer structure) where the switch and corresponding body tie 614 are fabricated on a same side (e.g., the front-side) of the SOI wafer. Moreover, the SOI wafers used to implement the switch 600 are very expensive.

In an off (shunt) condition, charge (e.g., current) is generated in the body 626 of the switch 600 and the body 626 becomes resistive. For example, when a voltage is applied to the drain or the source, charges (e.g., 616) are generated beneath a gate of the gate structure 602. To extract these charges, the charge 616 is moved along a path 620 of the gate to the body tie 614. However, the extraction process may generate more charges at the gate. When the generated charges are not extracted, the charges cause a shift in a breakdown voltage of the transistor or switch. In this case, the generated charge 616 increases the electrical potential in the body 626 and thereby reduces a breakdown voltage of the switch 600.

For example, in an SOI substrate transistor or switch, the body underlying the gate contact is isolated from a substrate by an insulating layer. Thus, the body is electrically floating. Most often, this floating body is undesirable because it causes problems in the SOI substrate transistor operation. For example, when an electron-hole pair is formed by ionization of a lattice atom by an electron, the hole migrates towards the source of the transistor. Because the body is not tied to the source, the excess holes generated collect in the body, thereby raising the body potential and, thus, modifying the transistor characteristics. The resulting change in voltage lowers an effective threshold voltage relative to the drain-to-source voltage, and increases the drain current.

One way to mitigate the breakdown voltage issue is to reduce a width of the switch 600 (e.g., to ≤twenty micrometer (20 μm)) to reduce the voltage drop of the charge and/or use an SOI substrate transistor to achieve a desirable performance. However, the reduction in width results in an increase in area and diminished design flexibility because several narrow switches (e.g., 10 μm to 15 μm) or very long switches may be specified to achieve sufficient switch performance. This follows because the voltage drop across narrow switches is small enough that it may be negligible and thus device performance can be maintained.

To mitigate these issues, aspects of the present disclosure are directed to a radio frequency integrated switch formed in a bulk semiconductor substrate. In contrast to the SOI substrate, hole migration is not a problem with transistors formed in a bulk silicon substrate, because the holes are attracted towards the substrate and away from the body. Aspects of the present disclosure are illustrated in the following figures.

FIG. 7 is a cross-sectional view of a radio frequency integrated circuit (RFIC) switch 700 having a bulk semiconductor wafer including a body tie on a backside of the bulk semiconductor wafer 420, according to aspects of the present disclosure. For illustrative purposes, some of the labelling and numbering of the devices and features of FIG. 7 are similar to those of FIG. 4. A layer transfer process with bulk wafer (e.g., illustrated in FIGS. 5A-5G) may achieve CMOS products such as CMOS transistors (e.g., the first active device 410), bipolar devices (e.g., vertical bipolar devices), CMOS switches, and passive components. The CMOS transistors may include, but are not limited to, planar field effect transistors (FETs), fin-type FETs (FinFETs), nanowire FETs, or other like FETs. The passive components may include resistors (e.g., vertical resistors) and diodes (e.g., vertical diodes).

In one aspect, a contact layer is deposited on the backside of the bulk semiconductor wafer. For example, as shown in FIG. 7, a backside contact layer 460 is deposited on the backside of the bulk semiconductor wafer 420 using a backside silicide process. The backside contact layer 460 may be used for the body tie or body contact for the radio frequency integrated circuit switch 700. For example, the body tie or backside contact layer 460 is at least one to two micrometers (1-2 μm) away from a gate (G) where the charges are generated. As a result, a switch 700 having a wider width (e.g., to >twenty micrometers (20 μm)) relative to the switch 600 may be achieved. The switch can also be as narrow as desirable.

The radio frequency integrated circuit switch 700 includes MOL interconnects (M0) as well as BEOL interconnects (M1). For example, the MOL interconnects (M0) and the BEOL interconnects (M1) may be coupled to the gate or the source/drain regions of the active devices (e.g., 410, 412, and 414). The MOL interconnects may include trench interconnects (e.g., trench interconnect 450) and vias for coupling active devices formed during a front-end-of-line processing to metallization layers formed during the back-end-of-line processing. The metallization configuration can be different from the metallization configuration of FIG. 7.

In this example, a zero-layer interconnect M0 is coupled to the drain D of the first active device 410. Another zero-layer interconnect M0 is coupled to the source S of the first active device 410. In addition, a first BEOL interconnect M1 is coupled to the zero-layer interconnect M0. Similarly, another BEOL interconnect M1 is coupled to the other zero-layer interconnect M0. The first BEOL interconnect M1 and the other BEOL interconnect M1 are formed as part of a front-side BEOL process.

In this configuration, a backside M1 metallization layer (e.g., a second-side metallization layer) is coupled to the first BEOL interconnect M1 through the trench interconnect 450. The trench interconnect 450 extends through a first deep trench isolation (DTI) region 430, from the front-side to the backside of the bulk semiconductor wafer 420. The backside metallization M1 may also be coupled to the backside contact layer 460.

When the radio frequency integrated circuit switch 700 is in an on-state (or through state) the body of the switch can be biased similar to a gate (G) of the radio frequency integrated circuit switch 700 to increase a drive current. When the radio frequency integrated circuit switch 700 is in an off-state (or shunt state) the body of the switch can be biased negatively, similar to the gate. This enables the body to collect additional carriers. For example, minority charge carriers (e.g., holes) are created in the body when the radio frequency integrated circuit switch 700 is in an off-state. It is desirable to remove the minority charge carriers from the device area so that the body does not bias independently from the gate by collecting the minority charge carriers (e.g., positive charges) that may turn on the radio frequency integrated circuit switch 700, thereby causing a breakdown in the device. To mitigate this issue, the body is biased using the backside contact layer 460 with a same bias as the gate. Thus, the minority charge carriers can be collected at the backside contact layer 460 when the radio frequency integrated circuit switch 700 is in the off-state to prevent the body from being at a free potential. For example, the backside contact layer 460 is negatively charged to attract the positive minority charge carriers. As a result, the body is maintained at or close to the gate voltage even when the radio frequency integrated circuit switch 700 is in an off-state.

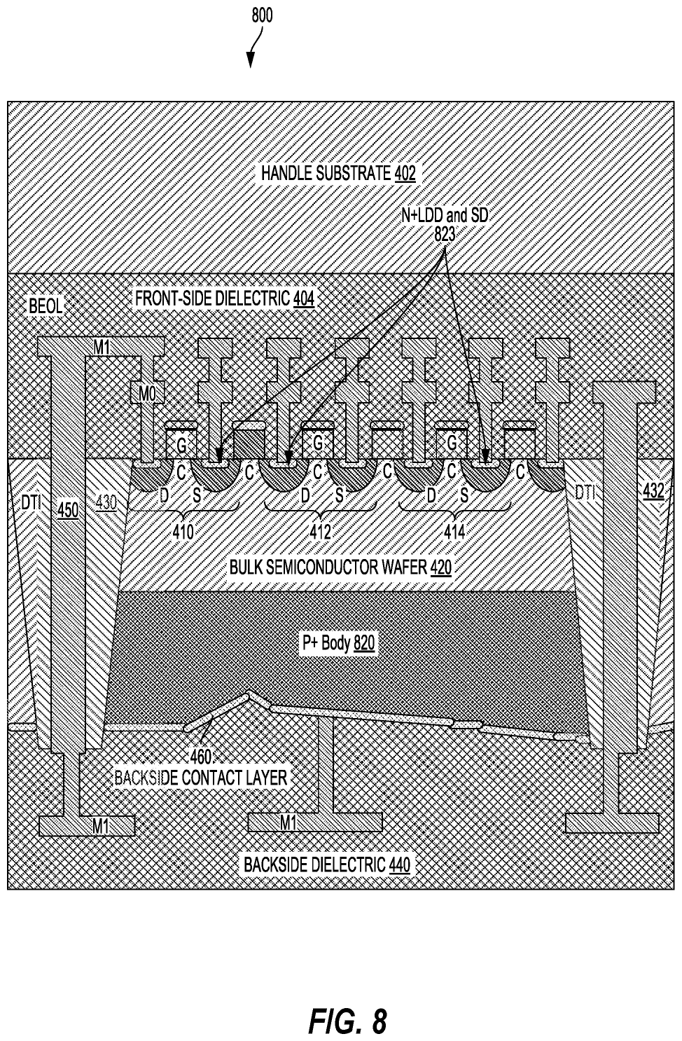

FIG. 8 is a cross-sectional view of a radio frequency integrated circuit (RFIC) switch 800 having a bulk semiconductor wafer including a body tie on a backside of the bulk semiconductor wafer 420, according to aspects of the present disclosure. For illustrative purposes, some of the labelling and numbering of the devices and features of FIG. 8 are similar to those of FIG. 4 and FIG. 7. For example, FIG. 8, which is similar to FIG. 7, further illustrates a P+ body 820 for the radio frequency integrated circuit switch 800. The P+ body 820 can be achieved in multiple ways. For example, the wafer can be an epitaxial wafer with a P+ substrate, which is still less expensive than a SOI wafer. In other aspects, the P+ body 820 of the wafer can be achieved by doping.

To achieve a desirable channel control, a thickness of the P+ body 820 may be within a defined range. For example, the P+ body 820 may be as close as thirty to forty nanometers (40-100 nm) from the gate or channel. The P+ body 820 may also be formed by ion implantation early in the bulk layer transfer process. The active region of the switch 800 can be implanted with a heavy implant of ions (N+) to the source and drain regions. In some aspects, the portion of the active region that lies below the gate G serves as a body of the switch 800 and the portions that are not below the gate G serve as the source S and drain D. In this configuration, the source S and the drain D are implanted with N+ ions as indicated at portions 823. The drain D may be a low doped drain. In certain approaches, the body extends below the source S and drain D regions. For example, if the switch 800 is implemented on a bulk substrate, the body includes the region of the substrate below the source S and drain D that was not altered by the heavy implant. In this case, the P+ region may be below the substrate to form the backside region of the substrate or wafer.

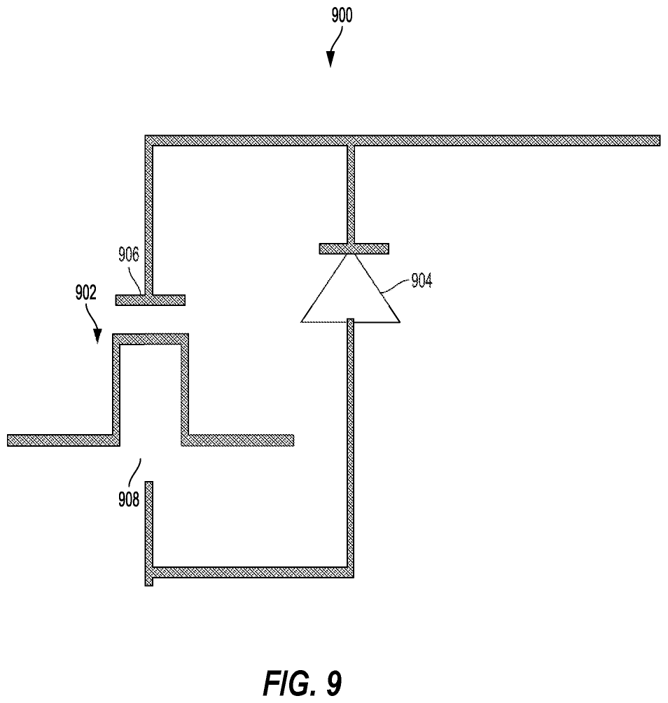

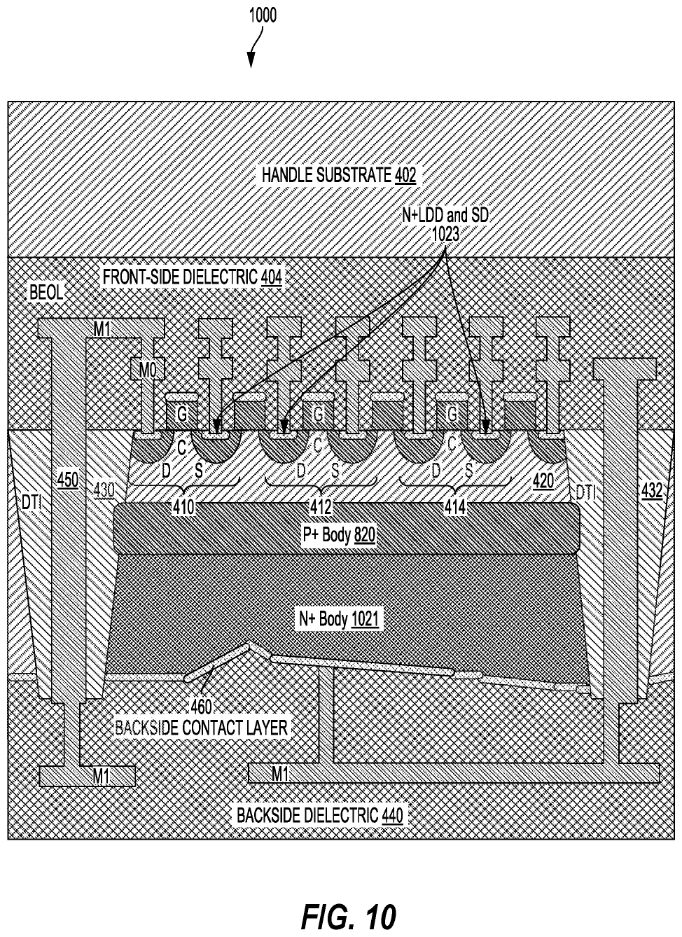

FIG. 9 illustrates an exemplary schematic of a radio frequency integrated circuit switch 900. The radio frequency integrated circuit switch 900 may include a transistor 902 and a diode 904. A gate 906 of the transistor 902 may be tied to a body 908 of the switch 900 via the diode 904. This improves the performance of the radio frequency integrated circuit switch 900 because in an on state, the diode 904 becomes a capacitor that is charged based on a voltage difference between the gate 906 and the body 908 of the transistor 902. In the off state, when charges are collected in the body, the diode 904 contributes to the extraction of those charges. For example, the diode 904 is forward biased to enable extraction of the charges. In SOI technology, the diode 904 is located beside the switch as an additional device. This configuration, however, increases the area used for the switch implementation. Accordingly, it is desirable to implement a diode for the switch while reducing the area occupied for the implementation of the switch. A desirable implementation is illustrated in FIG. 10.

FIG. 10 is a cross-sectional view of a radio frequency integrated circuit (RFIC) switch 1000 having a bulk semiconductor wafer including a body tie on a backside of the bulk semiconductor wafer, according to aspects of the present disclosure. For illustrative purposes, some of the labelling and numbering of the devices and features of FIG. 10 are similar to those of FIG. 8 and FIG. 9. In this aspect, the diode 904 is incorporated into the radio frequency integrated circuit switch 1000 and may be a P-N junction diode.

For example, the body of the radio frequency integrated circuit switch 1000 includes the P+ region or body 820 adjacent to an N+ body 1021 to form a P-N junction diode. A P-N junction diode is a two-terminal or two-electrode semiconductor device, which allows the electric current in only one direction while blocking the electric current in an opposite or reverse direction. When the N+ body is joined with the P+ body, a P-N junction is formed. The N+ body 1021 may be coupled between the P+ body 820 and the backside contact layer 460 to achieve the diode within the radio frequency integrated circuit switch 1000. Thus, there are no additional interconnects or wiring for the diode 904. The radio frequency integrated circuit switch 1000 may be configured in accordance with a FinFET structure or tri-gate structure.

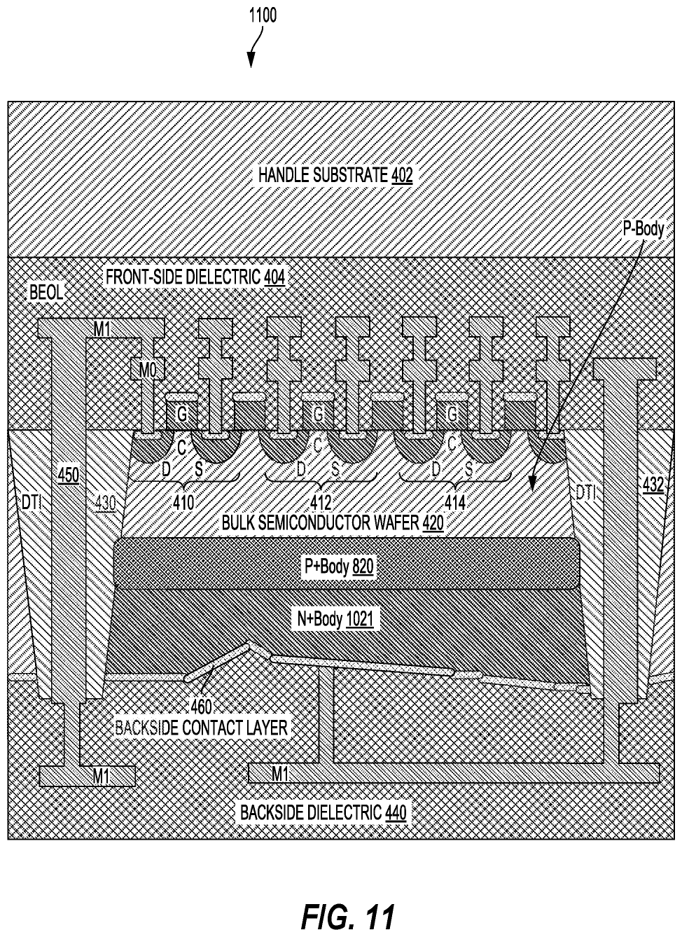

FIG. 11 is a cross-sectional view of a radio frequency integrated circuit (RFIC) switch 1100 having a bulk semiconductor wafer including a body tie on a backside of the bulk semiconductor wafer, according to aspects of the present disclosure. For illustrative purposes, some of the labelling and numbering of the devices and features of FIG. 11 are similar to those of FIG. 8, FIG. 9, and FIG. 10. In addition to the P-N junction diode, a resistor is also incorporated into the radio frequency integrated circuit switch 1100. For example, at least a portion of the bulk semiconductor wafer 420 can be formed into a resistor by controlling a distance from the channel C to the P+ body 820 and also controlling a doping concentration of the N+ body 1021 on at least a portion of the bulk semiconductor wafer 420.

In one aspect of the disclosure, the portion of the bulk semiconductor wafer 420 in which the resistor is formed is a section of the body of the radio frequency integrated circuit switch 1100. For example, the body of the radio frequency integrated circuit switch 1100 may include a first section, which is the first P-type region (P+) and a second section may be a second P-type region (P−). The second P-type region may be between the gate G of an active device or transistor (e.g., the third active device 414) and the first P-type region to form an internal body resistor.

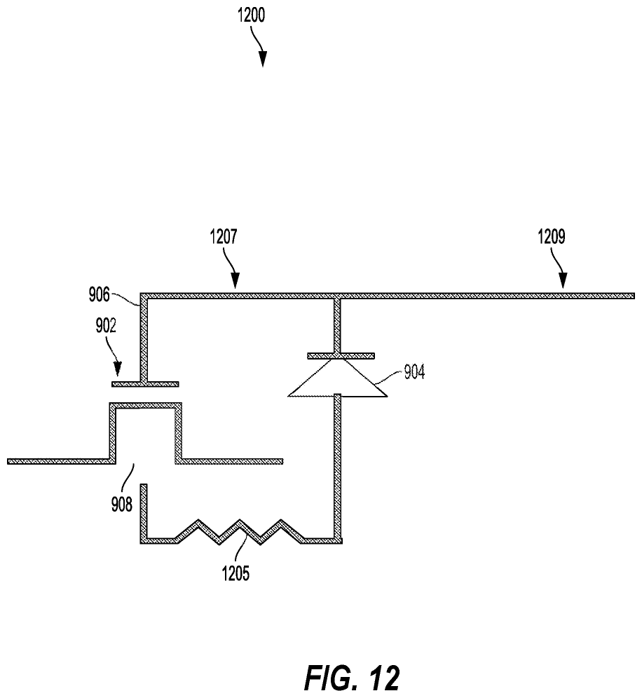

FIG. 12 illustrates an exemplary schematic of a radio frequency integrated circuit switch 1200 including a resistor 1205, according to aspects of the present disclosure. For illustrative purposes, some of the labelling and numbering of the devices and features of FIG. 12 are similar to those of FIG. 9. The resistor 1205 may be incorporated into the radio frequency integrated circuit switch 1200. The resistor 1205 may be coupled between the body 908 of the switch (e.g., a body of the transistor) and the diode 904. Optionally, an external gate resistor may be included at portion 1207 and/or a common gate/body resistor may be included at portion 1209 to implement the radio frequency integrated circuit switch 1200.

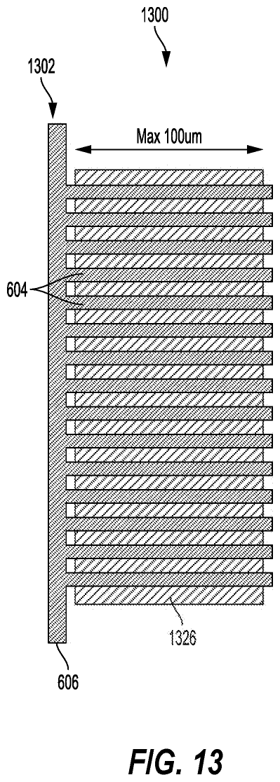

FIG. 13 illustrates an exemplary layout of a switch 1300 according to aspects of the present disclosure. For illustrative purposes, some of the labelling and numbering of the devices and features of FIG. 13 are similar to those of FIG. 6. The switch 1300 includes the body tie on the backside of the bulk semiconductor wafer. Because the body tie is on the backside of the bulk semiconductor wafer or body 1326 of the switch 1300, the body width may not extend beyond a gate structure 1302 to accommodate the body tie. In FIG. 6, for example, the width of the body 626 extends (see extended widths 624 and 628) beyond the width of the H-gate structure 602 to accommodate the body tie 614.

Moreover, the gate structure 1302 of FIG. 13 may not include the second parallel element 608, which is used to separate or isolate the body tie 614 from the active device region (e.g., N+ region). This follows because all of the charges generated in FIG. 13 are directed toward (e.g., downward) the backside contact layer 460, while the charges generated in the switch 600 traverse in different directions (e.g., sideways) toward the first parallel element 606 and the second parallel element 608. Thus, instead of traversing five micrometers or ten micrometers sideways as in FIG. 6, the generated charges are extracted by being directed downwardly about half a micrometer or one micrometer. For example, charge generated at the gates after ion implantation where the source S and drain D of the switch 1300 are doped with an N-type (N+) dopant are channeled downwardly through the P+ body 820.

The placement of the body tie at the backside of the bulk semiconductor wafer reduces the number of interconnections and frees up space. For example, the width of the switch 1300 can be increased to a desirable size (e.g., up to one hundred micrometers) with improved switch performance. For example, parasitic capacitance is reduced and the total area for the switch is reduced because a single switch can achieve performance of multiple switches.

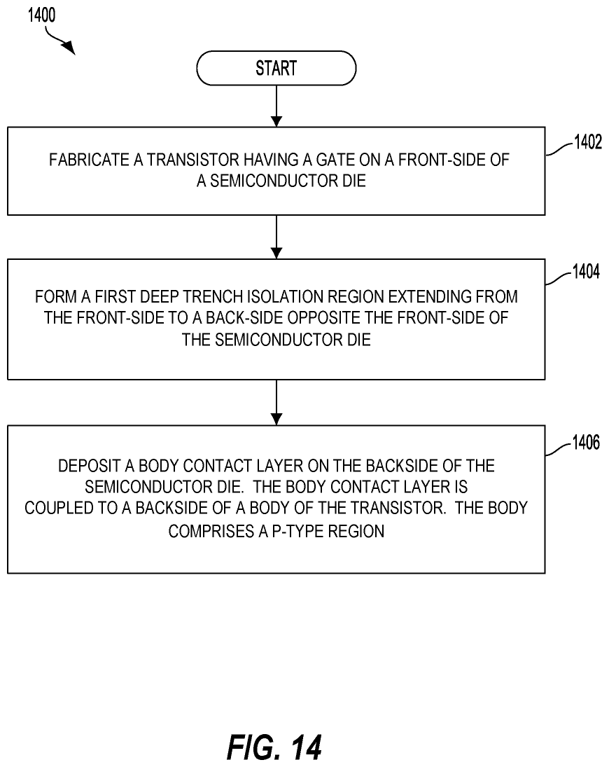

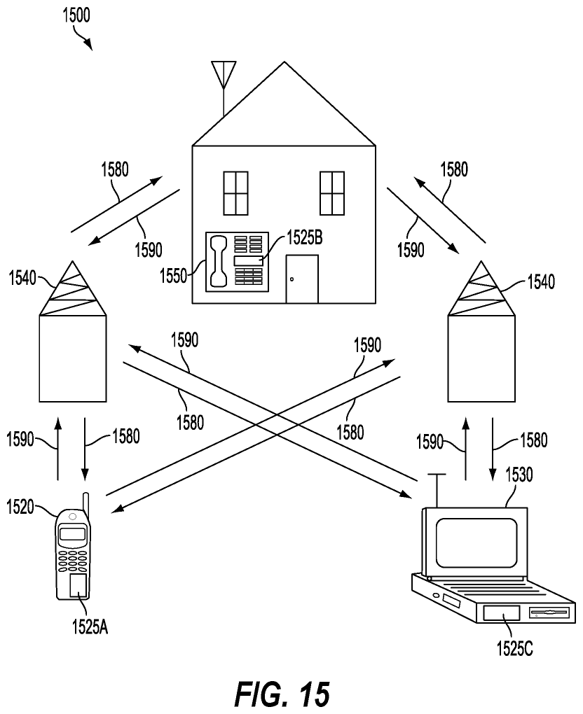

FIG. 14 is a process flow diagram illustrating a method 1400 of a bulk layer transfer process with second-side (e.g., backside) silicidation for constructing a radio frequency integrated circuit (RFIC) switch, according to an aspect of the present disclosure. In block 1402, a transistor having a gate is fabricated on a first-side of a semiconductor die (e.g., a bulk semiconductor substrate or wafer). For example, as shown in FIG. 4, a first active device 410 is fabricated on a first-side of a bulk semiconductor wafer 420. In block 1404, a first deep trench isolation region extending from the front-side to a backside opposite the front-side of the semiconductor die is formed. For example, as shown in FIG. 4, the first DTI region 430 extends from the first-side to the second-side of the bulk semiconductor wafer 420.

In block 1406, a body contact layer is deposited on the backside of the semiconductor die. The body contact layer is coupled to a backside of a body of the transistor. The body includes a first P-type region. For example, as shown in FIG. 5E, the backside contact layer 460 is deposited on the backside of the bulk semiconductor wafer 420 using a backside silicide process. Furthermore, FIG. 8 illustrates the backside contact layer 460 coupled to a backside of the P+ body 820.

According to a further aspect of the present disclosure, a radio frequency integrated circuit switch, including a bulk semiconductor wafer having an active device on a first-side and a deep trench isolation region extending from the first-side to a second-side opposite the first-side of the bulk semiconductor wafer, is described. The radio frequency integrated circuit includes means for collecting minority charge carriers channeled from the body of the active device (e.g., transistor) when the radio frequency integrated circuit switch is in an off-state. The minority charge carriers collecting means may be the backside contact layer 460, shown in FIGS. 5E, 5F, 7, 8, 10, and 11. In another aspect, the aforementioned means may be any module or any apparatus configured to perform the functions recited by the aforementioned means.

FIG. 15 is a block diagram showing an exemplary wireless communication system 1500 in which an aspect of the disclosure may be advantageously employed. For purposes of illustration, FIG. 15 shows three remote units 1520, 1530, and 1550 and two base stations 1540. It will be recognized that wireless communication systems may have many more remote units and base stations. Remote units 1520, 1530, and 1550 include IC devices 1525A, 1525C, and 1525B that include the disclosed RFIC switch. It will be recognized that other devices may also include the disclosed RFIC switch, such as the base stations, switching devices, and network equipment. FIG. 15 shows forward link signals 1580 from the base station 1540 to the remote units 1520, 1530, and 1550 and reverse link signals 1590 from the remote units 1520, 1530, and 1550 to base stations 1540.

In FIG. 15, remote unit 1520 is shown as a mobile telephone, remote unit 1530 is shown as a portable computer, and remote unit 1550 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 15 illustrates remote units according to the aspects of the disclosure, the disclosure is not limited to these exemplary illustrated units. Aspects of the disclosure may be suitably employed in many devices, which include the disclosed RFIC switch.

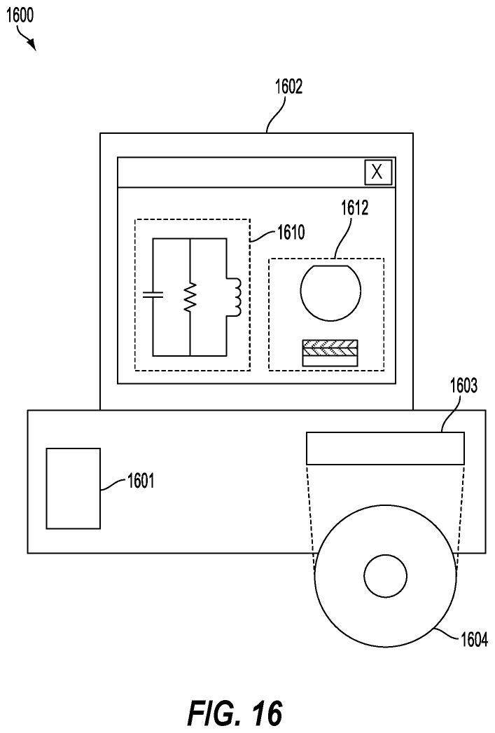

FIG. 16 is a block diagram illustrating a design workstation used for circuit, layout, and logic design of a semiconductor component, such as the RF devices disclosed above. A design workstation 1600 includes a hard disk 1601 containing operating system software, support files, and design software such as Cadence or OrCAD. The design workstation 1600 also includes a display 1602 to facilitate a circuit design 1610 or an RFIC switch design 1612. A storage medium 1604 is provided for tangibly storing the circuit design 1610 or the RFIC switch design 1612. The circuit design 1610 or the RFIC switch design 1612 may be stored on the storage medium 1604 in a file format such as GDSII or GERBER. The storage medium 1604 may be a CD-ROM, DVD, hard disk, flash memory, or other appropriate device. Furthermore, the design workstation 1600 includes a drive apparatus 1603 for accepting input from or writing output to the storage medium 1604.

Data recorded on the storage medium 1604 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1604 facilitates the circuit design 1610 or the RFIC switch design 1612 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

1. A radio frequency integrated circuit switch, comprising:
a semiconductor die comprising a transistor having a gate on a front-side of the semiconductor die, a first deep trench isolation region extending from the front-side to a backside opposite the front-side of the semiconductor die;
a body contact layer on the backside of the semiconductor die and coupled to a backside of a body of the transistor, in which the body comprises a first P-type region, in which the body contact layer comprises a conductive material on an entire length of the backside of the semiconductor die; and
a backside dielectric layer on a surface of the body contact layer, opposite the body of the transistor.

2. The radio frequency integrated circuit switch of claim 1, in which the first deep trench isolation region extends through the body contact layer and into the backside dielectric layer.

3. The radio frequency integrated circuit switch of claim 1, in which the body of the transistor further comprises an N-type region between the first P-type region and the body contact layer to form an embedded diode.

4. The radio frequency integrated circuit switch of claim 1, in which the body of the transistor further comprises a second P-type region between the gate of the transistor and the first P-type region to form an internal body resistor, in which the second P-type region is less doped than the first P-type region.

5. The radio frequency integrated circuit switch of claim 1, in which the transistor comprises a Fin field effect transistor (FinFET) or a tri-gate structure.

6. The radio frequency integrated circuit switch of claim 1, in which the semiconductor die comprises a bulk semiconductor substrate.

7. The radio frequency integrated circuit switch of claim 6, in which the body contact layer comprises a silicide layer on an entire length of a backside of the bulk semiconductor substrate.

8. The radio frequency integrated circuit switch of claim 1, integrated into a radio frequency front end module, the radio frequency front end module incorporated into at least one of a music player, a video player, an entertainment unit, a navigation device, a communications device, a personal digital assistant (PDA), a fixed location data unit, a mobile phone, and a portable computer.

9. A method of constructing a radio frequency integrated circuit switch, comprising:
fabricating a transistor having a gate on a front-side of a semiconductor die;
forming a first deep trench isolation region extending from the front-side to a backside opposite the front-side of the semiconductor die; and
depositing a body contact layer on the backside of the semiconductor die, in which the body contact layer is coupled to a backside of a body of the transistor, the body comprising a first P-type region.

10. The method of claim 9, further comprising depositing a backside dielectric layer on the body contact layer, in which the first deep trench isolation region extends through the body contact layer and into the backside dielectric layer.

11. The method of claim 9, further comprising forming an embedded diode within the body of the transistor, in which the body of the transistor comprises an N-type region between the first P-type region and the body contact layer.

12. The method of claim 9, further comprising forming an internal body resistor within the body of the transistor, in which the body of the transistor comprises a second P-type region between the gate of the transistor and the first P-type region, in which the second P-type region is less doped than the first P-type region.

13. The method of claim 9, in which depositing the body contact layer comprises depositing a silicide layer on the backside of the semiconductor die to form the body contact layer.

14. The method of claim 9, further comprising integrating the radio frequency integrated circuit switch into a radio frequency front end module, the radio frequency front end module incorporated into at least one of a music player, a video player, an entertainment unit, a navigation device, a communications device, a personal digital assistant (PDA), a fixed location data unit, a mobile phone, and a portable computer.

15. A radio frequency front end module, comprising:
a wireless transceiver, comprising a semiconductor die comprising a transistor having a gate on a front-side of the semiconductor die, a first deep trench isolation region extending from the front-side to a backside opposite the front-side of the semiconductor die, a body contact layer on the backside of the semiconductor die and coupled to a backside of a body of the transistor, the body comprising a first P-type region, in which the body contact layer comprises a conductive material on an entire length of the backside of the semiconductor die, and a backside dielectric layer on a surface of the body contact layer, opposite the body of the transistor; and
an antenna coupled to an output of the wireless transceiver.

16. The radio frequency front end module of claim 15, in which the first deep trench isolation region extends through the body contact layer and into the backside dielectric layer.

17. The radio frequency front end module of claim 15, in which the body of the transistor further comprises an N-type region between the first P-type region and the body contact layer to form an embedded diode.

18. The radio frequency front end module of claim 15, in which the body of the transistor further comprises a second P-type region between the gate of the transistor and the first P-type region to form an internal body resistor, in which the second P-type region is less doped than the first P-type region.

19. The radio frequency front end module of claim 15, in which the transistor comprises a Fin field effect transistor (FinFET) or a tri-gate structure.

20. The radio frequency front end module of claim 15, incorporated into at least one of a music player, a video player, an entertainment unit, a navigation device, a communications device, a personal digital assistant (PDA), a fixed location data unit, a mobile phone, and a portable computer.
